(19) United States
(12) Patent Application Publication
(10) Pub. No.: US 2018/0322230 A1
(43) Pub. Date: Nov. 8, 2018

(54) DRIVERLESS VEHICLE SIMULATION TEST METHOD AND APPARATUS, DEVICE AND READABLE MEDIUM

(71) Applicant: BAIDU ONLINE NETWORK TECHNOLOGY (BEIJING) CO., LTD., Haidian District Beijing (CN)

(72) Inventor: Zheng HAN, Haidian District Beijing (CN)

(73) Assignee: BAIDU ONLINE NETWORK TECHNOLOGY (BEIJING) CO., LTD., Haidian District Beijing (CN)

(21) Appl. No.: 15/961,717

(22) Filed: Apr. 24, 2018

(30) Foreign Application Priority Data
May 8, 2017 (CN) 2017103174920

(51) Int. Cl. G06F 17/50; G05D 1/00; G06K 9/00; G06F 17/30

(52) U.S. Cl. CPC G06F 17/5009; G06F 17/5095; G06F 17/3082; G06K 9/00765; G05D 1/0088

(57) ABSTRACT

The present disclosure provides a driverless vehicle simulation test method and apparatus, a device and a readable medium. According to the present disclosure, an accident video is obtained from an accident video database of a traffic management department; corresponding accident scenario information is obtained according to the accident videos; a simulated accident scenario is constructed according to the accident scenario information, and vehicle behaviors of the simulated driverless vehicle in the simulated accident scenario are tested. With the accident video being obtained from the accident video database of the traffic management department, the present disclosure can ensure authenticity and accuracy of the simulated accident scenario for simulation test of the driverless vehicle, therefore can perform real and valid test for the driverless vehicle and effectively improve the accuracy and validity of the driverless vehicle simulation test.

The present application claims the priority of Chinese Patent Application No. 2017103174920, filed on May 8, 2017, with the title of “Driverless vehicle simulation test method and apparatus, device and readable medium”. The disclosure of the above applications is incorporated herein by reference in its entirety.

### FIELD OF THE DISCLOSURE

The present disclosure relates to the technical field of computer application, and particularly to a driverless vehicle simulation test method and apparatus, a device and a readable medium.

### BACKGROUND OF THE DISCLOSURE

A driverless vehicle is a smart vehicle, may also called a wheeled type mobile robot, and implements unmanned driving mainly by virtue of a smart driving instrument in the vehicle with a computer system as a kernel. The driverless vehicle integrates many technologies such as automatic control, system structure, artificial intelligence and visual computing, is a product resulting from computer sciences, mode recognition and smart control technology, is an important sign of a country's scientific research strength and industrial levels, and has a broad application prospect in the fields such as national defense and national economy.

At present, driverless vehicles are still in a constant development and test phase. Tests of the driverless vehicles may be classified into two portions: offline text and on-road test. The on-road test is dangerous and costly. The offline test may be performed by making full use of a simulator. The simulator is similar to a computer device. Upon testing, a series of simulation scenarios may be input in the simulator, and the simulator may output the driverless vehicle's behaviors in the simulation scenarios. In this way, it is possible to judge whether the driverless vehicle's actual behaviors conform to desired behaviors. In the prior art, simulation scenarios are mostly constructed by a tester subjectively according to observed traffic accidents and mastered basic theories. Many constructed simulation scenarios are not reasonable enough and cannot simulate real scenarios.

Since many simulation scenarios constructed in the prior art cannot simulate real scenarios, it is impossible to perform real and valid simulation test for the driverless vehicle.

### SUMMARY OF THE DISCLOSURE

The present disclosure provides a driverless vehicle simulation test method and apparatus, a device and a readable medium, to implement real and valid simulation test of the driverless vehicle.

The present disclosure provides a driverless vehicle simulation test method, wherein the method comprises:

obtaining an accident video from an accident video database of a traffic management department;

obtaining corresponding accident scenario information according to the accident video;

constructing a simulated accident scenario according to the accident scenario information, and testing vehicle behaviors of a simulated driverless vehicle in the simulated accident scenario.

Further optionally, in the method, the obtaining an accident video from an accident video database of a traffic management department specifically comprises:

filtering the accident video database of the traffic management department to get the accident video with a motor vehicle accident tag.

Further optionally, in the method, the obtaining corresponding accident scenario information according to the accident video specifically comprises:

screening the accident video to get a first image frame at a time instant when the accident happens;

obtaining, from the accident video, multiple second image frames which are before the first image frame at the time instant when the accident happens and can record travel trajectories of an accident vehicle and an accident object other than the accident vehicle;

obtaining the accident scenario information according to the multiple second image frames and the first image frame.

Further optionally, in the method, the obtaining the accident scenario information according to the multiple second image frames and the first image frame specifically comprises:

according to the first image frame and the respective second image frames, extracting the accident vehicle and its travel trajectory, the accident object and its travel trajectory;

extracting a road topological structure of an accident site according to the first image frame and the respective second image frames.

Further optionally, in the method, the obtaining the accident scenario information according to the multiple second image frames and the first image frame further comprises:

extracting time when the accident happens according to the first image frame and respective second image frames; and/or extracting weather conditions when the accident happens according to the first image frame and respective second image frames.

Further optionally, in the method, the obtaining the accident scenario information according to the multiple second image frames and the first image frame specifically comprises:

displaying the multiple second image frames and the first image frame to a tester so that the tester constitutes the accident scenario information according to the multiple second image frames and the first image frame;

receiving the accident scenario information input by the tester.

The present disclosure provides a driverless vehicle simulation test apparatus, comprising:

a video obtaining module configured to obtain an accident video from an accident video database of a traffic management department;

a scenario information obtaining module configured to obtain corresponding accident scenario information according to the accident video;

a simulation test module configured to construct a simulated accident scenario according to the accident scenario information, and test vehicle behaviors of the simulated driverless vehicle in the simulated accident scenario.

Further optionally, in the apparatus, the video obtaining module is specifically configured to filter the accident video database of the traffic management department to get the accident video with a motor vehicle accident tag.

Further optionally, in the apparatus, the scenario information obtaining module is specifically configured to:

screen the accident video to get a first image frame at a time instant when the accident happens;

obtain, from the accident video, multiple second image frames which are before the first image frame at the time instant when the accident happens and can record travel trajectories of an accident vehicle and an accident object other than the accident vehicle;

obtain the accident scenario information according to the multiple second image frames and the first image frame.

Further optionally, in the apparatus, the scenario information obtaining module is specifically configured to:

according to the first image frame and the respective second image frames, extract the accident vehicle and its travel trajectory, the accident object and its travel trajectory;

extract a road topological structure of an accident site according to the first image frame and the respective second image frames.

Further optionally, in the apparatus, the scenario information obtaining module is further specifically configured to:

extract time when the accident happens according to the first image frame and respective second image frames; and/or

extract weather conditions when the accident happens according to the first image frame and respective second image frames.

Further optionally, in the apparatus, the scenario information obtaining module is specifically configured to:

display the multiple second image frames and the first image frame to a tester so that the tester constitutes the accident scenario information according to the multiple second image frames and the first image frame;

receive the accident scenario information input by the tester.

The present disclosure further provides a computer device, comprising:

one or more processors,

a memory for storing one or more programs,

the one or more programs, when executed by said one or more processors, enabling said one or more processors to implement the aforesaid driverless vehicle simulation test method.

The present disclosure further provides a computer readable medium on which a computer program is stored, the program, when executed by the processor, implementing the aforesaid driverless vehicle simulation test method.

According to the driverless vehicle simulation test method and apparatus, a device and a readable medium, an accident video is obtained from an accident video database of a traffic management department; corresponding accident scenario information is obtained according to the accident videos; a simulated accident scenario is constructed according to the accident scenario information, and vehicle behaviors of the simulated driverless vehicle in the simulated accident scenario are tested. With the accident video being obtained from the accident video database of the traffic management department, the present disclosure can ensure authenticity and accuracy of the simulated accident scenario for simulation test of the driverless vehicle, therefore can perform real and valid test for the driverless vehicle and effectively improve the accuracy and validity of the driverless vehicle simulation test.

### BRIEF DESCRIPTION OF DRAWINGS

FIG. 1 is a flow chart of a driverless vehicle simulation test method according to an embodiment of the present disclosure.

FIG. 2 is a block diagram of a driverless vehicle simulation test apparatus according to an embodiment of the present disclosure.

FIG. 3 is a block diagram of a computer device according to an embodiment of the present disclosure.

FIG. 4 is an example diagram of a computer device according to the present disclosure.

### DETAILED DESCRIPTION OF PREFERRED EMBODIMENTS

The present disclosure will be described in detail in conjunction with figures and specific embodiments to make objectives, technical solutions and advantages of the present disclosure more apparent.

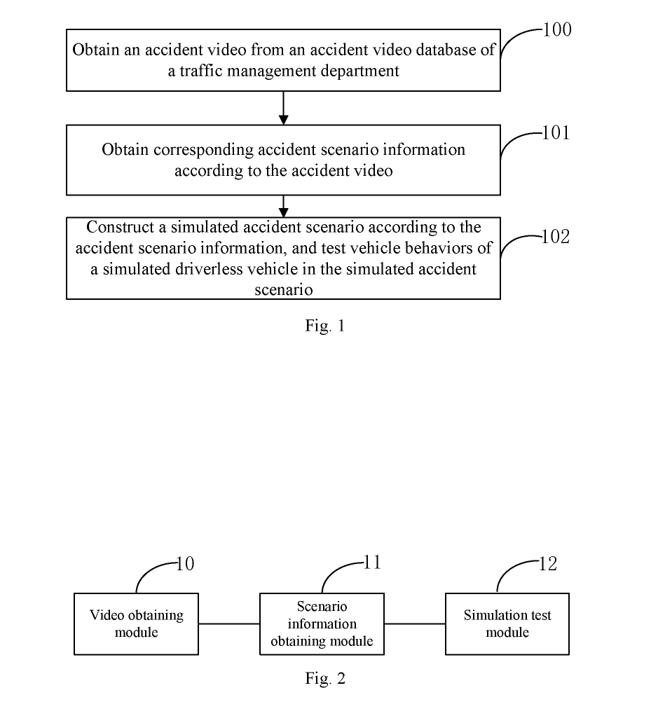

FIG. 1 is a flow chart of a driverless vehicle simulation test method according to an embodiment of the present disclosure. As shown in FIG. 1, the driverless vehicle simulation test method according to the present embodiment may specifically comprise the following steps:

100: obtaining an accident video from an accident video database of a traffic management department;

A subject for executing the driverless vehicle simulation test method according to the present embodiment is a driverless vehicle simulation test apparatus. The driverless vehicle simulation test apparatus may comprise a hardware portion and a software portion, for example, the hardware portion may comprise a simulator similar to a computer; a software program for implementing the driverless vehicle simulation test method according to the present embodiment may run on the simulator. Meanwhile, the hardware portion may further comprise a display which may be used to display the driverless vehicle simulation test procedure, test results and the like. in addition, the simulation test apparatus may further carry peripheral devices similar to a mouse, a keyboard or other devices which can control the simulation test procedure, which will not be detailed here one by one.

In practical application, the traffic management department installs one or more cameras and speed-measuring instruments at places such as arterial roads and crossroads of the city. These devices cover all road conditions at crossroads. When vehicles collide or scratch, the cameras capture the accident videos earliest. Furthermore, these accident videos captured by the cameras are true and accurate. The traffic management department stores these accident videos captured by cameras at the crossroads in an accident video database of the traffic management department. To effectively manage the accident videos, accident tags are usually added in the videos, for example, the accident tags may include motor vehicle accidents or non-motor vehicle accidents. Furthermore, the motor vehicle accident tags may be further classified into freight vehicle accidents, passenger vehicle accidents, car accidents and the like.

The present embodiment takes into consideration authenticity and validity of accident videos in the accident video database of the traffic management department. The accident videos are not artificially speculated, but result from accidents really happening on roads, and have a very high research value. Therefore, authentic and valid accident videos are obtained from the accident video database of the traffic management department to perform simulation test for the driverless vehicle. Hence, implementation of the driverless vehicle simulation test method in the present embodiment requires cooperation with the traffic management department and requires access to the accident video database of the traffic management department to obtain the accident videos. For example, if the accident video database of the traffic management department is classified according to motor vehicle accident video database and non-motor accident video database, when the driverless vehicle simulation test of the present embodiment is performed, communication can be directly conducted with the motor vehicle accident video database to obtain motor vehicle accident videos therefrom for direct use. Alternatively, all accident videos in the accident video database of the traffic management department are stored in the same database, and identified by motor vehicle accident tags and non-motor vehicle accident tags. At this time, optionally, the step 100 “obtaining an accident video from an accident video database of a traffic management department” may specifically comprise filtering to get accident videos whose tags are motor vehicle accidents from the accident video database of the traffic management department. A reason for selecting accident videos of motor vehicle accidents in the present embodiment is that upon the driverless vehicle simulation test, the driverless vehicle can only simulate travel trajectories of the motor vehicles and perform simulation test.

101: obtaining corresponding accident scenario information according to the accident video;

The accident video obtained in the present embodiment records the whole procedure of the accident. For example, the accident video may specifically comprise positions, travel directions and travel trajectories of an accident vehicle and the other accident object before the happening of the accident, causes for the accident, accident results and the like. Then, the corresponding scenario information of the accident may be obtained according to all information recorded in the accident video and related to this accident. The accident vehicle in the present embodiment is a vehicle to be simulated by a simulated driverless vehicle in the driverless vehicle simulation test. The simulated driverless vehicle in the present embodiment may be generated by simulating performance parameters of the driverless vehicle according to software. The other accident object in the present embodiment may also be a motor vehicle, a non-motor vehicle, a pedestrian, other obstacles or the like, and will not be detailed one by one here. Likewise, the accident object may also be generated by simulating with software according to parameter information of the other party of the accident during simulation test.

102: constructing a simulated accident scenario according to the accident scenario information, and testing vehicle behaviors of the simulated driverless vehicle in the simulated accident scenario.

In the present embodiment, after the scenario information of the accident is obtained, it is feasible to construct the simulated accident scenario in the simulator for performing simulation test according to the scenario information of the accident, then, in the simulated accident scenario, control the simulated driverless vehicle to simulate behaviors of the accident vehicle, thereby testing the vehicle behaviors of the simulated driverless vehicle in the simulated accident scenario. Since the simulated driverless vehicle is simulated according to according to performance parameters of the driverless vehicle, the simulated driverless vehicle's behaviors in the simulated accident scenario represent the driverless vehicle's behaviors in the corresponding real accident scenario. Test focuses on whether the simulated driverless vehicle has an urgent danger-avoiding capability in the real accident scenario, and whether it can avoid occurrence of a traffic accident. According to the simulation test, if the simulated driverless vehicle has a poor danger-avoiding capability, the performance parameters of the driverless vehicle may be adjusted so that the driverless vehicle is in a real accident scenario corresponding to the simulated accident scenario, can automatically control and handle to avoid occurrence of the traffic accident and thereby effectively improve the safety of the driverless vehicle.

According to the driverless vehicle simulation test method of the present embodiment, an accident video is obtained from an accident video database of a traffic management department; corresponding accident scenario information is obtained according to the accident videos; a simulated accident scenario is constructed according to the accident scenario information, and vehicle behaviors of the simulated driverless vehicle in the simulated accident scenario are tested. With the accident video from the accident video database of the traffic management department being obtained, the present embodiment can ensure authenticity and accuracy of the simulated accident scenario for simulation test of the driverless vehicle, therefore can perform real and valid test for the driverless vehicle and effectively improve the accuracy and validity of the driverless vehicle simulation test.

Furthermore optionally, on the basis of the technical solution of the embodiment shown in FIG. 1, step 101 “obtaining corresponding accident scenario information according to the accident video” may specifically comprise the following steps:

(a1) screening the accident video to get a first image frame at a time instant when the accident happens;

(a2) obtaining, from the accident video, multiple second image frames which are before the first image frame at the time instant when the accident happens and can record travel trajectories of the accident vehicle and the accident object other than the accident vehicle;

(a3) obtaining accident scenario information according to the multiple second image frames and the first image frame.

For example, in the present embodiment, the driverless vehicle simulation test apparatus may employ an image recognition technology to screen the accident video to obtain the first image frame at the time instant when the accident happens, which may determine the state when the accident happens, for example, the accident vehicle scratches another vehicle which is considered as the other accident object in the accident, or the accident vehicle collides a bicycle or a pedestrian or another obstacle which is considered as the other accident object in the accident. Then, the driverless vehicle simulation test apparatus may seek forward from the first image frame, and obtain, from the accident video, the multiple second image frames before the first image frame at the time instant when the accident happens. The multiple second image frames obtained here can record travel trajectories of the accident vehicle and the accident object other than the accident vehicle so that the whole procedure of the whole accident can be clearly seen. Then, the driverless vehicle simulation test apparatus extracts accident scenario information according to the multiple second image frames and the first image frame.

For example, further optionally, step (a3) “obtaining accident scenario information according to the multiple second image frames and the first image frame” may specifically comprise the following step:

(b1) according to the first image frame and the multiple second image frames, extracting the accident vehicle and its travel trajectory, the accident object and its travel trajectory.

Since both parties of the accident are the most important elements in the accident, after both parties and their respective travel trajectories in the true accident are obtained, it is possible to subsequently employ the driverless vehicle to simulate the accident vehicle in the accident, and travel according to the travel trajectory of the accident vehicle in the accident and perform simulation test.

(b2) extracting a road topological structure of an accident site according to the first image frame and the respective second image frames.

In an actual traffic accident, the road itself has many objective conditions that cannot be changed so that accident happening is inevitable. Therefore, in the present embodiment, it is necessary to extract the road topological structure of an accident site according to the first image frame and the second image frames.

Or furthermore, after step (a2) “obtaining, from the accident video, multiple second image frames which are before the first image frame at the time instant when the accident happens and can record travel trajectories of the accident vehicle and the accident object other than the accident vehicle”, there may be include a step of obtaining, from the accident video, multiple third image frames after the first image frame at the time instant when the accident happens. As such, it is possible to further obtain more accurate accident scenario information according to the processing after the accident. For example, sometimes the accident scenario captured before the accident might not clearly seen due to the problem of the angle of the camera. For example, when the accident happens, there is a pedestrian or obstacle on a side blocked by the accident vehicle or the accident object; in order to ensure the pedestrian safe or the obstacle from damages, the accident vehicle and the accident object cannot turn, thereby causing the accident. At this time, the accident scenario information may be obtained by referring to the multiple third image frames, the multiple second image frames together with the first image frame.

Further optionally, upon obtaining the multiple third image frames, the step (b2) “extracting a road topological structure of an accident site according to the first image frame and the second image frames” may specifically comprise extracting a road topological structure of an accident site according to the first image frame, the respective second image frames and respective third image frames. As such, it is possible to more easily clearly see the road topological structure according to scenario situations after the clearing after the accident. In this way, the extracted road topological structure is more accurate.

Further optionally, step (a3) “obtaining accident scenario information according to the multiple second image frames and the first image frame” may further comprise the following steps in addition to the above steps (b1) and (b2):

(b3) extracting time of happening of the accident according to the first image frame and respective second image frames; and/or

(b4) extracting weather conditions when the accident happens according to the first image frame and respective second image frames.

In practical application, there might be many other factors causing the happening of the accident, for example the problem of light. If light is poor, the driver might cannot clearly see or cannot see road conditions so that the accident happens. Therefore, in the present embodiment, upon obtaining the accident scenario information, it is further feasible to extract the time of happening of the accident according to the first image frame and respective second image frames. Therefore, the video captured by the camera carries video-shooting time. Hence, the time of happening of the accident may be obtained according to the first image frame and respective second image frames. In addition, weather conditions might cause the happening of the accident, for example, if the road surface has rain water or snow, tires might skid, thereby causing the happening of the accident. Therefore, in the present embodiment, upon obtaining the accident scenario information, it is further feasible to extract weather conditions when the accident happens according to the first image frame and respective second image frames.

In practical application, other scenario information may be obtained. If the obtained scenario information includes more types of information, the simulated accident scenario constructed subsequently according to the accident scenario information can better simulate the real scenario, and the tested behaviors of the driverless vehicle are more accurate. As such, safety performance of the driverless vehicle may be judged according to the driverless vehicle's behaviors. If the safety performance is low, modification and adjustment may be performed in time. Hence, the driverless vehicle simulation test method according to the present embodiment facilitates improving the driverless vehicle's safety.

The above manner of obtaining corresponding accident scenario information according to the accident video may be automatically extracted by the driverless vehicle simulation test according to the accident video. Optionally, in the present embodiment it is also possible for a tester to generate the accident scenario information and manually input. For example further optionally, on the basis of the technical solution of the embodiment shown in FIG. 1, step 101 “obtaining corresponding accident scenario information according to the accident video” may specifically comprise the following steps:

(c1) displaying the multiple second image frames and the first image frame to the tester so that the tester constitutes the accident scenario information according to the multiple second image frames and the first image frame;

(c2) receiving the accident scenario information input by the tester.

In this solution, it is feasible to obtain the multiple second image frames and the first image frame, and display the multiple second image frames and the first image frame to the tester, for example, display in turn in time sequence of frames so that the tester constitutes the accident scenario information according to the multiple second image frames and the first image frame. The accident scenario information constructed by the tester may be directly described with words. Therefore, the tester may further perform inputting the accident scenario information constructed in the words form into the driverless vehicle simulation test apparatus through a human-machine interface module such as a mouse or keyboard.

The driverless vehicle simulation test apparatus receives the accident scenario information input by the tester, and subsequently constructs the simulated accident scenario according to the accident scenario information, and tests behaviors of the simulated driverless vehicle in the simulated accident scenario, for example, it may construct the simulated road topological structure according to the road topological structure of the accident site, construct a simulated accident object according to the accident object, control the simulated driverless vehicle and the simulated accident object in the simulated road topological structure, allow the simulated driverless vehicle to travel according to the travel trajectory of the accident vehicle and the simulated accident object to travel according to the travel trajectory of the accident object, and test the behaviors of the simulated driverless vehicle. Since the performance parameters of the simulated driverless vehicle are performance parameters of the driverless vehicle and the simulated accident object simulates the performance of the accident object, according to the simulation test method in the present embodiment, the driverless vehicle in the present embodiment is disposed in the real accident scenario and the driverless vehicle's behaviors in the real scenario are tested. For example, in the simulation test, if the simulated driverless vehicle can brake in time to avoid the happening of the accident, this indicates that the corresponding driverless vehicle reacts very quickly, and the braking system is very sensitive, thereby avoiding the traffic accident. If in the simulation test the simulated driverless vehicle is caught in an accident, the performance parameters of the driverless vehicle are adjusted at this time according to the test results, for example, shorten reaction time, improve sensitivity of the detector, find an obstacle in time, or lower the accident happening rate of the driverless vehicle by changing a travel direction such as taking a sudden turn upon detecting an obstacle, and improve the safety of the simulated driverless vehicle.

In addition, it needs to be appreciated that when step 101 “obtaining corresponding accident scenario information according to the accident video” is performed, it is further possible to obtain a travel speed of the accident vehicle and the accident object when the accident happens. For example, it is feasible to obtain two frames from the multiple second image frames and the first image frame, select a travel distance between the two frames according to a shooting proportion of the camera and suitable references, and then predict the travel speed of the accident vehicle when the accident happens according to the predicted distance and time between the two frames. It is further feasible to directly obtain an average travel speed of other similar vehicles on the road where the accident happens, as the travel speed of the accident vehicle when the accident happens. Likewise, it is also feasible to employ other similar methods to predict the travel speed of the accident object when the accident happens. As such, in the present embodiment, upon constructing the simulated accident scenario according to the accident scenario information and testing the behaviors of the simulated driverless vehicle in the simulated accident scenario, it is further feasible to control the travel speed of the simulated driverless vehicle and the travel speed of the accident object, to perform simulation test more accurately.

In practical application, if the travel speeds of the accident vehicle and the accident object when the accident happens are not obtained in the simulated scenario information, it is also possible, upon performing simulation test, constantly adjust the speed of the simulated driverless vehicle according to a limit speed of the road where the accident happens, and perform test for the driverless vehicle at each speed level. If the accident object is a vehicle, adjustment is also adjusted according to the limit speed of the road where the accident happens. If the accident object is a pedestrian or a bicycle, the simulation test may be performed with reference to a usual travel speed of the pedestrian or bicycle. If the accident object is other obstacles, the travel speed is predicted in the same manner, and will not be detailed any more here.

According to the driverless vehicle simulation test method of the above embodiment, a real accident video is obtained from an accident video database of the traffic management department, and the simulated accident scenario is constructed according to the real accident video, thereby ensuring authenticity and accuracy of the simulated accident scenario for simulation test of the driverless vehicle, performing real and valid test for the driverless vehicle and effectively improving the accuracy and validity of the driverless vehicle simulation test.

FIG. 2 is a block diagram of a driverless vehicle simulation test apparatus according to an embodiment of the present disclosure. As shown in FIG. 2, the driverless vehicle simulation test apparatus according to the embodiment comprises a video obtaining module 10, a scenario information obtaining module 11 and a simulation test module 12.

The video obtaining module 10 is configured to obtain an accident video from an accident video database of a traffic management department;

The scenario information obtaining module 11 is configured to obtain corresponding accident scenario information according to the accident video obtained by the video obtaining module 10;

The simulation test module 12 is configured to construct a simulated accident scenario according to the accident scenario information obtained by the scenario information obtaining module 11, and test vehicle behaviors of the simulated driverless vehicle in the simulated accident scenario.

Principles employed by the driverless vehicle simulation test apparatus of the present embodiment to implement driverless vehicle simulation test with the above modules and the resultant technical effects are the same as those of the above-mentioned method embodiment. For particulars, please refer to the depictions of the aforesaid relevant method embodiment, and no detailed depictions will be presented here.

Further optionally, on the basis of the technical solution of the embodiment shown in FIG. 2, the video obtaining module 10 is specifically configured to filter the accident video database of the traffic management department to get the accident video with a motor vehicle accident tag.

Further optionally, on the basis of the technical solution of the embodiment shown in FIG. 2, the scenario information obtaining module 11 is specifically configured to:

screen the accident video to get a first image frame at a time instant when the accident happens;

obtain, from the accident video, multiple second image frames which are before the first image frame at the time instant when the accident happens and can record travel trajectories of the accident vehicle and the accident object other than the accident vehicle;

obtain the accident scenario information according to the multiple second image frames and the first image frame.

Further optionally, on the basis of the technical solution of the embodiment, the scenario information obtaining module 11 is specifically configured to: according to the first image frame and the multiple second image frames, extract the accident vehicle and its travel trajectory, the accident object and its travel trajectory;

extract a road topological structure of an accident site according to the first image frame and the respective second image frames.

Further optionally, on the basis of the technical solution of the embodiment, the scenario information obtaining module 11 is further specifically configured to:

extract time of happening of the accident according to the first image frame and respective second image frames; and/or

extract weather conditions when the accident happens according to the first image frame and respective second image frames.

Further optionally, on the basis of the technical solution of the embodiment shown in FIG. 2, the scenario information obtaining module 11 is specifically configured to:

display the multiple second image frames and the first image frame to a tester so that the tester constitutes the accident scenario information according to the multiple second image frames and the first image frame;

receive the accident scenario information input by the tester.

Principles employed by the driverless vehicle simulation test apparatus of the present embodiment to implement driverless vehicle simulation test with the above modules and the resultant technical effects are the same as those of the above-mentioned method embodiment. For particulars, please refer to the depictions of the aforesaid relevant method embodiment, and no detailed depictions will be presented here.

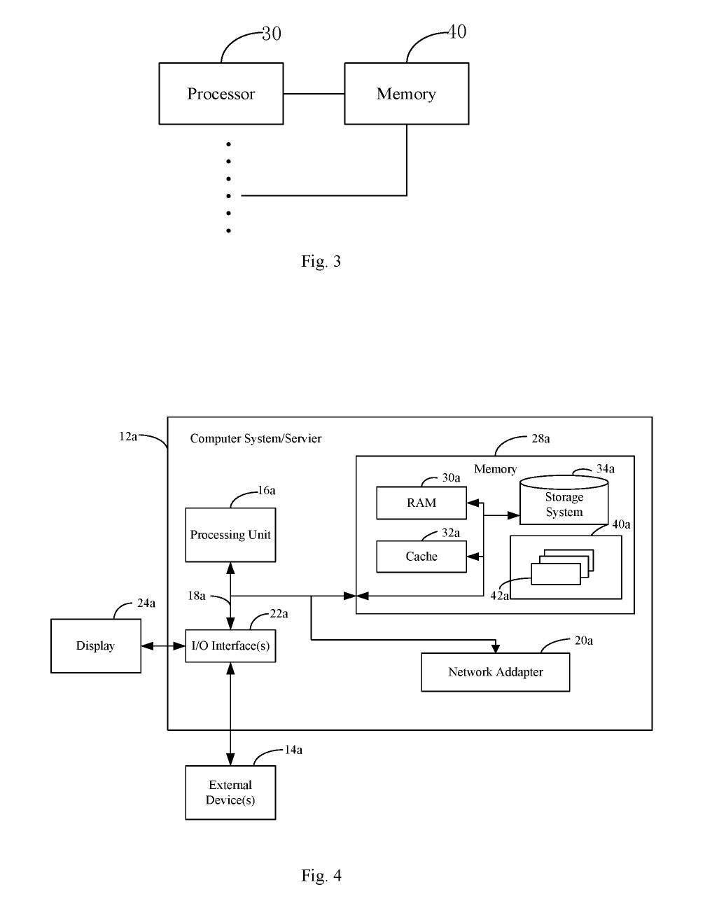

FIG. 3 is a block diagram of an embodiment of a computer device according to the present disclosure. As shown in FIG. 3, the computer device according to the present embodiment comprises: one or more processors 30, and a memory 40 for storing one or more programs, the one or more programs stored in the memory 40, when executed by said one or more processors 30, enabling said one or more processors 30 to implement the driverless vehicle simulation test method of the embodiments shown in FIG. 1-FIG. 3. The embodiment shown in FIG. 3 exemplarily includes a plurality of processors 30. That is to say, the computer device of the present embodiment is similar to a simulated test apparatus for implementing the driverless vehicle simulation test.

For example, FIG. 4 is an example diagram of a computer device according to an embodiment of the present disclosure. FIG. 4 shows a block diagram of an example computer device 12a adapted to implement an implementation mode of the present disclosure. The computer device 12a shown in FIG. 4 is only an example and should not bring about any limitation to the function and scope of use of the embodiments of the present disclosure.

As shown in FIG. 4, the computer device 12a is shown in the form of a general-purpose computing device. The components of computer device 12a may include, but are not limited to, one or more processors 16a, a system memory 28a, and a bus 18a that couples various system components including the system memory 28a and the processors 16a.

Bus 18a represents one or more of several types of bus structures, including a memory bus or memory controller, a peripheral bus, an accelerated graphics port, and a processor or local bus using any of a variety of bus architectures. By way of example, and not limitation, such architectures include Industry Standard Architecture (ISA) bus, Micro Channel Architecture (MCA) bus, Enhanced ISA (EISA) bus, Video Electronics Standards Association (VESA) local bus, and Peripheral Component Interconnect (PCI) bus.

Computer device 12a typically includes a variety of computer system readable media. Such media may be any available media that is accessible by computer device 12a, and it includes both volatile and non-volatile media, removable and non-removable media.

The system memory 28a can include computer system readable media in the form of volatile memory, such as random access memory (RAM) 30a and/or cache memory 32a. Computer device 12a may further include other removable/non-removable, volatile/non-volatile computer system storage media. By way of example only, storage system 34a can be provided for reading from and writing to a non-removable, non-volatile magnetic media (not shown in FIG. 4 and typically called a “hard drive”). Although not shown in FIG. 4, a magnetic disk drive for reading from and writing to a removable, non-volatile magnetic disk (e.g., a “floppy disk”), and an optical disk drive for reading from or writing to a removable, non-volatile optical disk such as a CD-ROM, DVD-ROM or other optical media can be provided. In such instances, each drive can be connected to bus 18a by one or more data media interfaces. The system memory 28a may include at least one program product having a set (e.g., at least one) of program modules that are configured to carry out the functions of embodiments shown in FIG. 1-FIG. 2 of the present disclosure.

Program/utility 40a, having a set (at least one) of program modules 42a, may be stored in the system memory 28a by way of example, and not limitation, as well as an operating system, one or more disclosure programs, other program modules, and program data. Each of these examples or a certain combination thereof might include an implementation of a networking environment. Program modules 42a generally carry out the functions and/or methodologies of embodiments shown in FIG. 1-FIG. 2 of the present disclosure.

Computer device 12a may also communicate with one or more external devices 14a such as a keyboard, a pointing device, a display 24a, etc.; with one or more devices that enable a user to interact with computer device 12a; and/or with any devices (e.g., network card, modem, etc.) that enable computer device 12a to communicate with one or more other computing devices. Such communication can occur via Input/Output (I/O) interfaces 22a. Still yet, computer device 12a can communicate with one or more networks such as a local area network (LAN), a general wide area network (WAN), and/or a public network (e.g., the Internet) via network adapter 20a. As depicted in FIG. 4, network adapter 20a communicates with the other communication modules of computer device 12a via bus 18a. It should be understood that although not shown, other hardware and/or software modules could be used in conjunction with computer device 12a. Examples, include, but are not limited to: microcode, device drivers, redundant processing units, external disk drive arrays, RAID systems, tape drives, and data archival storage systems, etc.

The processor 16a executes various function applications and data processing by running programs stored in the system memory 28a, for example, implements the driverless vehicle simulation test method shown in the above embodiments.

The present disclosure further provides a computer readable medium on which a computer program is stored, the program, when executed by the processor, implementing the driverless vehicle simulation test method shown in the above embodiments.

The computer readable medium of the present embodiment may include RAM30a, and/or cache memory 32a and/or a storage system 34a in the system memory 28a in the embodiment shown in FIG. 4.

As science and technology develops, a propagation channel of the computer program is no longer limited to tangible medium, and it may also be directly downloaded from the network or obtained in other manners. Therefore, the computer readable medium in the present embodiment may include a tangible medium as well as an intangible medium.

The computer-readable medium of the present embodiment may employ any combinations of one or more computer-readable media. The machine readable medium may be a machine readable signal medium or a machine readable storage medium. A machine readable medium may include, but not limited to, an electronic, magnetic, optical, electromagnetic, infrared, or semiconductor system, apparatus, or device, or any suitable combination of the foregoing. More specific examples of the machine readable storage medium would include an electrical connection having one or more wires, a portable computer diskette, a hard disk, a random access memory (RAM), a read-only memory (ROM), an erasable programmable read-only memory (EPROM or Flash memory), a portable compact disc read-only memory (CD-ROM), an optical storage device, a magnetic storage device, or any suitable combination of the foregoing. In the text herein, the computer readable storage medium can be any tangible medium that include or store programs for use by an instruction execution system, apparatus or device or a combination thereof.

The computer-readable signal medium may be included in a baseband or serve as a data signal propagated by part of a carrier, and it carries a computer-readable program code therein. Such propagated data signal may take many forms, including, but not limited to, electromagnetic signal, optical signal or any suitable combinations thereof. The computer-readable signal medium may further be any computer-readable medium besides the computer-readable storage medium, and the computer-readable medium may send, propagate or transmit a program for use by an instruction execution system, apparatus or device or a combination thereof.

The program codes included by the computer-readable medium may be transmitted with any suitable medium, including, but not limited to radio, electric wire, optical cable, RF or the like, or any suitable combination thereof.

Computer program code for carrying out operations disclosed herein may be written in one or more programming languages or any combination thereof. These programming languages include an object oriented programming language such as Java, Smalltalk, C++ or the like, and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

In the embodiments provided by the present disclosure, it should be understood that the revealed system, apparatus and method can be implemented in other ways. For example, the above-described embodiments for the apparatus are only exemplary, e.g., the division of the units is merely logical one, and, in reality, they can be divided in other ways upon implementation.

The units described as separate parts may be or may not be physically separated, the parts shown as units may be or may not be physical units, i.e., they can be located in one place, or distributed in a plurality of network units. One can select some or all the units to achieve the purpose of the embodiment according to the actual needs.

Further, in the embodiments of the present disclosure, functional units can be integrated in one processing unit, or they can be separate physical presences; or two or more units can be integrated in one unit. The integrated unit described above can be implemented in the form of hardware, or they can be implemented with hardware plus software functional units.

The aforementioned integrated unit in the form of software function units may be stored in a computer readable storage medium. The aforementioned software function units are stored in a storage medium, including several instructions to instruct a computer device (a personal computer, server, or network equipment, etc.) or processor to perform some steps of the method described in the various embodiments of the present disclosure. The aforementioned storage medium includes various media that may store program codes, such as U disk, removable hard disk, Read-Only Memory (ROM), a Random Access Memory (RAM), magnetic disk, or an optical disk.

What are stated above are only preferred embodiments of the present disclosure and not intended to limit the present disclosure. Any modifications, equivalent substitutions and improvements made within the spirit and principle of the present disclosure all should be included in the extent of protection of the present disclosure.

What is claimed is:

1. A driverless vehicle simulation test method, wherein the method comprises:
obtaining an accident video from an accident video database of a traffic management department;
obtaining corresponding accident scenario information according to the accident video;
constructing a simulated accident scenario according to the accident scenario information, and testing vehicle behaviors of a simulated driverless vehicle in the simulated accident scenario.

2. The method according to claim 1, wherein the obtaining an accident video from an accident video database of a traffic management department specifically comprises:
filtering the accident video database of the traffic management department to get the accident video with a motor vehicle accident tag.

3. The method according to claim 1, wherein the obtaining corresponding accident scenario information according to the accident video specifically comprises:
screening the accident video to get a first image frame at a time instant when the accident happens;
obtaining, from the accident video, multiple second image frames which are before the first image frame at the time instant when the accident happens and can record travel trajectories of an accident vehicle and an accident object other than the accident vehicle;
obtaining the accident scenario information according to the multiple second image frames and the first image frame.

4. The method according to claim 3, wherein the obtaining the accident scenario information according to the multiple second image frames and the first image frame specifically comprises:
according to the first image frame and the respective second image frames, extracting the accident vehicle and its travel trajectory, the accident object and its travel trajectory;
extracting a road topological structure of an accident site according to the first image frame and the respective second image frames.

5. The method according to claim 4, wherein the obtaining the accident scenario information according to the multiple second image frames and the first image frame further comprises:
extracting time when the accident happens according to the first image frame and respective second image frames; and/or
extracting weather conditions when the accident happens according to the first image frame and respective second image frames.

6. The method according to claim 3, wherein the obtaining the accident scenario information according to the multiple second image frames and the first image frame specifically comprises:
displaying the multiple second image frames and the first image frame to a tester so that the tester constitutes the accident scenario information according to the multiple second image frames and the first image frame;
receiving the accident scenario information input by the tester.

7. A computer device, wherein the computer device comprises:
one or more processors,
a memory for storing one or more programs,
the one or more programs, when executed by said one or more processors, enabling said one or more processors to implement the following operation:
obtaining an accident video from an accident video database of a traffic management department;
obtaining corresponding accident scenario information according to the accident video;
constructing a simulated accident scenario according to the accident scenario information, and testing vehicle behaviors of a simulated driverless vehicle in the simulated accident scenario.

8. The computer device according to claim 7, wherein the obtaining an accident video from an accident video database of a traffic management department specifically comprises:
filtering the accident video database of the traffic management department to get the accident video with a motor vehicle accident tag.

9. The computer device according to claim 7, wherein the obtaining corresponding accident scenario information according to the accident video specifically comprises:
screening the accident video to get a first image frame at a time instant when the accident happens;
obtaining, from the accident video, multiple second image frames which are before the first image frame at the time instant when the accident happens and can record travel trajectories of an accident vehicle and an accident object other than the accident vehicle;
obtaining the accident scenario information according to the multiple second image frames and the first image frame.

10. The computer device according to claim 9, wherein the obtaining the accident scenario information according to the multiple second image frames and the first image frame specifically comprises:
according to the first image frame and the respective second image frames, extracting the accident vehicle and its travel trajectory, the accident object and its travel trajectory;
extracting a road topological structure of an accident site according to the first image frame and the respective second image frames.

11. The computer device according to claim 10, wherein the obtaining the accident scenario information according to the multiple second image frames and the first image frame further comprises:
extracting time when the accident happens according to the first image frame and respective second image frames; and/or
extracting weather conditions when the accident happens according to the first image frame and respective second image frames.

12. The computer device according to claim 9, wherein the obtaining the accident scenario information according to the multiple second image frames and the first image frame specifically comprises:
displaying the multiple second image frames and the first image frame to a tester so that the tester constitutes the accident scenario information according to the multiple second image frames and the first image frame;
receiving the accident scenario information input by the tester.

13. A computer readable medium on which a computer program is stored, wherein the program, when executed by the processor, implements the following operation:
obtaining an accident video from an accident video database of a traffic management department;
obtaining corresponding accident scenario information according to the accident video;
constructing a simulated accident scenario according to the accident scenario information, and testing vehicle behaviors of a simulated driverless vehicle in the simulated accident scenario.

14. The computer readable medium according to claim 13, wherein the obtaining an accident video from an accident video database of a traffic management department specifically comprises:
filtering the accident video database of the traffic management department to get the accident video with a motor vehicle accident tag.

15. The computer readable medium according to claim 13, wherein the obtaining corresponding accident scenario information according to the accident video specifically comprises:
screening the accident video to get a first image frame at a time instant when the accident happens;
obtaining, from the accident video, multiple second image frames which are before the first image frame at the time instant when the accident happens and can record travel trajectories of an accident vehicle and an accident object other than the accident vehicle;
obtaining the accident scenario information according to the multiple second image frames and the first image frame.

16. The computer readable medium according to claim 15, wherein the obtaining the accident scenario information according to the multiple second image frames and the first image frame specifically comprises:
according to the first image frame and the respective second image frames, extracting the accident vehicle and its travel trajectory, the accident object and its travel trajectory;
extracting a road topological structure of an accident site according to the first image frame and the respective second image frames.

17. The computer readable medium according to claim 16, wherein the obtaining the accident scenario information according to the multiple second image frames and the first image frame further comprises:
extracting time when the accident happens according to the first image frame and respective second image frames; and/or
extracting weather conditions when the accident happens according to the first image frame and respective second image frames.

18. The computer readable medium according to claim 15, wherein the obtaining the accident scenario information according to the multiple second image frames and the first image frame specifically comprises:
displaying the multiple second image frames and the first image frame to a tester so that the tester constitutes the accident scenario information according to the multiple second image frames and the first image frame;
receiving the accident scenario information input by the tester.
